(19) United States
(12) Patent Application Publication
(10) Pub. No.: US 2002/0089063 A1
(43) Pub. Date: Jul. 11, 2002

(54) Copper dual damascene interconnect technology

(76) Inventors: Kie Y. Ahn, Chappaqua, NY (US); Leonard Forbes, Corvallis, OR (US)

Correspondence Address: DICKSTEIN SHAPIRO MORIN & OSHINSKY LLP, 2101 L STREET NW, WASHINGTON, DC, 20037-1526, US

(21) Appl. No.: 09/755,071

(22) Filed: Jan. 8, 2001

(51) Int. Cl. H01L 21/44; H01L 23/48

(52) U.S. Cl. 257/762; 438/687

(57) ABSTRACT

A copper damascene structure including a titanium-silicon-nitride barrier layer formed by organic-metallic atomic layer deposition is disclosed. Copper is selectively deposited by a CVD process and/or by an electroless deposition technique.

### FIELD OF THE INVENTION

The present invention relates to the field of semiconductors and, in particular, to a method of forming damascene structures in semiconductor devices.

### BACKGROUND OF THE INVENTION

The integration of a large number of components on a single integrated circuit (IC) chip requires complex interconnects. Ideally, the interconnect structures should be fabricated with minimal signal delay and optimal packing density. The reliability and performance of integrated circuits may be affected by the quality of their interconnect structures. Advanced multiple metallization layers have been used to accommodate higher packing densities as devices shrink below sub-0.25 micron design rules. One such metallization scheme is a dual damascene structure formed by a dual damascene process. The dual damascene process is a two-step sequential mask/etch process to form a two-level structure, such as a via connected to a metal line situated above the via.

As illustrated in FIG. 1, a known dual damascene process as applied to interconnect formation begins with the deposition of a first insulating layer 14 over a first level interconnect metal layer 12, which in turn is formed over or within a semiconductor substrate 10. A second insulating layer 16 is next formed over the first insulating layer 14. An etch stop layer 15 is typically formed between the first and second insulating layers 14, 16. The second insulating layer 16 is patterned by photolithography with a first mask (not shown) to form a trench 17 corresponding to a metal line of a second level interconnect. The etch stop layer 15 prevents the upper level trench pattern 17 from being etched through to the first insulating layer 14.

As illustrated in FIG. 2, a second masking step follows ed by an etch step are applied to form a via 18 through the etch stop layer 15 and the first insulating layer 14. After the etching is completed, both the trench 17 and the via 18 are filled with metal 20, which is typically copper (Cu), to form a damascene structure 25, as illustrated in FIG. 3.

If desired, a second etch stop layer (not shown) may be formed between the substrate 10 and the first insulating layer 14 during the formation of the dual damascene structure 25. In any event, and in contrast to a single damascene process, the via and the trench are simultaneously filled with metal. Thus, compared to the single damascene process, the dual damascene process offers the advantage of process simplification and low manufacturing cost.

In an attempt to improve the performance, reliability and density of the interconnects, the microelectronics industry has recently begun migrating away from the use of aluminum (Al) and/or its alloys for the interconnects. As such, advanced dual damascene processes have begun using copper (Cu) as the material of choice because copper has high conductivity, extremely low resistivity (about 1.7 μΩcm) and good resistance to electromigration. Unfortunately, copper diffuses rapidly through silicon dioxide (SiO₂) or other interlayer dielectrics, such as polyimides and parylenes, and copper diffusion can destroy active devices, such as transistors and capacitors, formed in the IC substrate. In addition, metal adhesion to the underlying substrate materials must be excellent to form reliable interconnect structures but the adhesion of copper to interlayer dielectrics, particularly to SiO₂, is generally poor.

Accordingly, there is a need for an improved damascene process which reduces production costs and increases productivity. There is also a need for a method of increasing the adhesion of copper to underlying damascene layers as well as a method of decreasing copper diffusion in such layers.

### SUMMARY OF THE INVENTION

The present invention provides a method for fabricating a copper damascene interconnect structure in a semiconductor device which requires fewer processing steps and reduces the diffusion of copper atoms to underlying damascene layers.

In an exemplary embodiment, trenches and vias are formed according to damascene processing, subsequent to which a thin Ti—Si—N diffusion barrier layer is formed by an organo-metallic atomic layer deposition inside the trenches and vias. A selective copper CVD process is used to fill in the trenches and vias with copper. In another exemplary embodiment, an electroless deposition technique is employed in lieu of the selective copper CVD process. This way, the adhesion of copper atoms to the underlying layers is increased, while the diffusion of copper atoms into adjacent interconnect layers is suppressed.

Additional advantages of the present invention will be more apparent from the detailed description and accompanying drawings, which illustrate preferred embodiments of the invention.

### BRIEF DESCRIPTION OF THE DRAWINGS

FIG. 1 is a cross-sectional view of a conventional semiconductor device at a preliminary stage of production.

FIG. 2 is a cross-sectional view of the semiconductor device of FIG. 1 at a subsequent stage of production.

FIG. 3 is a cross-sectional view of the semiconductor device of FIG. 2 at a subsequent stage of production.

FIG. 4 is a cross-sectional view of a semiconductor device at a preliminary stage of production and in accordance with a first embodiment of the present invention.

FIG. 5 is a cross-sectional view of the semiconductor device of FIG. 4 at a subsequent stage of production.

FIG. 6 is a cross-sectional view of the semiconductor device of FIG. 4 at a subsequent stage of production.

FIG. 7 is a cross-sectional view of the semiconductor device of FIG. 4 at a subsequent stage of production.

FIG. 8 is a cross-sectional view of the semiconductor device of FIG. 4 at a subsequent stage of production.

FIG. 9 is a cross-sectional view of the semiconductor device of FIG. 4 at a subsequent stage of production.

FIG. 10 is a cross-sectional view of the semiconductor device of FIG. 4 at a subsequent stage of production.

FIG. 11 is a cross-sectional view of the semiconductor device of FIG. 4 at a subsequent stage of production.

FIG. 12 is a cross-sectional view of the semiconductor device of FIG. 4 at a subsequent stage of production.

FIG. 13 is a cross-sectional view of the semiconductor device of FIG. 4 at a subsequent stage of production.

FIG. 14 is a cross-sectional view of the semiconductor device of FIG. 4 at a subsequent stage of production.

FIG. 15 is a cross-sectional view of a semiconductor device constructed in accordance with a second embodiment of the present invention.

FIG. 16 is a cross-sectional view of the semiconductor device of FIG. 15 at a subsequent stage of production.

FIG. 17 is a cross-sectional view of a semiconductor device constructed in accordance with a third embodiment of the present invention.

FIG. 18 illustrates a computer system having a memory cell with a copper damascene structure according to the present invention

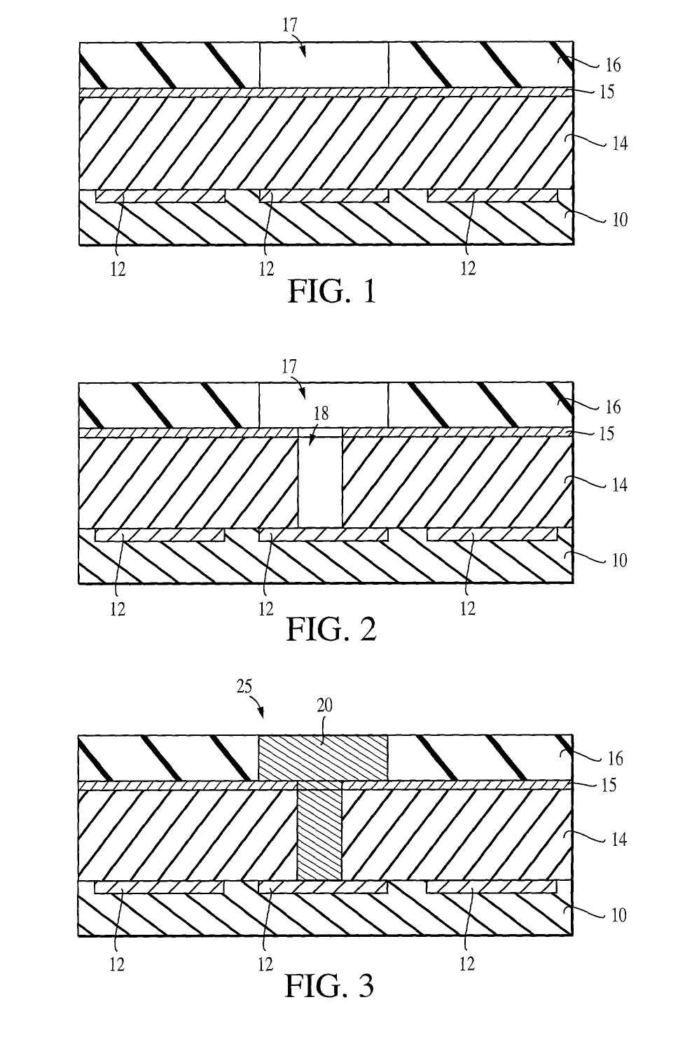

### DETAILED DESCRIPTION OF PREFERRED EMBODIMENTS

In the following detailed description, reference is made to various specific embodiments in which the invention may be practiced. These embodiments are described with sufficient detail to enable those skilled in the art to practice the invention, and it is to be understood that other embodiments may be employed, and that structural and electrical changes may be made without departing from the spirit or scope of the present invention.

The term “substrate” used in the following description may include any semiconductor-based structure that has a semiconductor surface. The term should be understood to include silicon, silicon-on insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could be silicon-germanium, germanium, or gallium arsenide. When reference is made to a “substrate” in the following description, previous process steps may have been utilized to form regions or junctions in or on the base semiconductor or foundation.

The term “copper” is intended to include not only elemental copper, but also copper with other trace metals or in various alloyed combinations with other metals as known in the art, as long as such alloy retains the physical and chemical properties of copper. The term “copper” is also intended to include conductive oxides of copper.

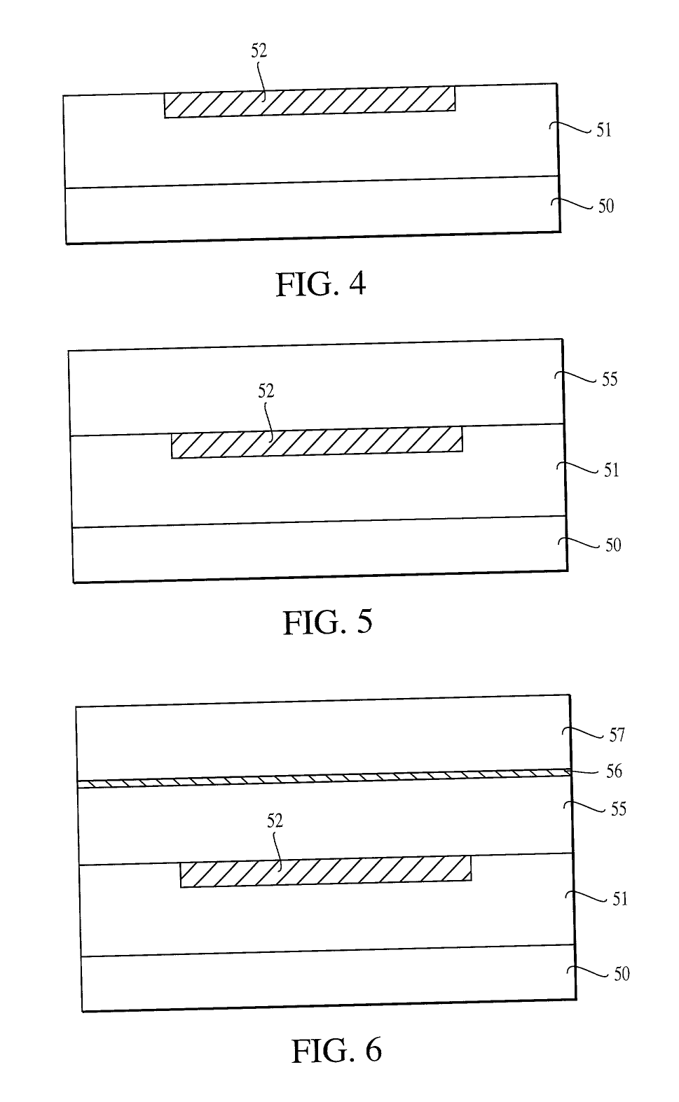

Referring now to the drawings, w,here like elements are designated by like reference numerals, FIGS. 4-18 illustrate the formation of copper damascene structures 100, 200, 300 (FIGS. 14, 16, 17) formed in accordance with exemplary embodiments of the present invention. FIG. 4 depicts a portion of an insulating layer 51 formed over a semiconductor substrate 50, on or within which a metal layer 52 has been formed. The metal layer 52 represents a lower metal interconnect layer which is to be later interconnected with an upper copper interconnect layer. The metal layer 52 may be formed of copper (Cu), but other conductive materials, such as tungsten (W) or aluminum (Al) and their alloys, may be used also.

Referring now to FIG. 5, a first intermetal insulating layer 55 is formed overlying the insulating layer 51 and the metal layer 52. In an exemplary embodiment of the present invention, the first intermetal insulating layer 55 is blanket deposited by spin coating to a thickness of about 2,000 Angstroms to 15,000 Angstroms, more preferably of about 6,000 Angstroms to 10,000 Angstroms. The first intermetal insulating layer 55 may be cured at a predefined temperature, depending on the nature of the material. Other known deposition methods, such as sputtering by chemical vapor deposition (CVD), plasma enhanced CVD (PECVD), or physical vapor deposition (PVD), may be used also for the formation of the first intermetal insulating layer 55, as desired.

The first intermetal insulting layer 55 may be formed of a conventional insulating oxide, such as silicon oxide (SiO₂), or a low dielectric constant material such as, for example, polyimide, spin-on-polymers (SOP), parylene, flare, polyarylethers, polytetrafluoroethylene, benzocyclobutene (BCB), SILK, fluorinated silicon oxide (FSG), NANOGLASS or hydrogen silsesquioxane, among others. The present invention is not limited, however, to the above-listed materials and other insulating and/or dielectric materials known in the industry may be used also.

Next, as illustrated in FIG. 6, a second intermetal insulating layer 57 is formed overlying an etch stop layer 56 and below a copper metal layer that will be formed subsequently. The second intermetal insulating layer 57 may be formed, for example, by deposition to a thickness of about 2,000 Angstroms to about 15,000 Angstroms, more preferably of about 6,000 Angstroms to 10,000 Angstroms. Other deposition methods, such as the ones mentioned above with reference to the formation of the first intermetal insulating layer 55 may be used also. The second intermetal insulating layer 57 may be formed of the same material used for the formation of the first intermetal insulating layer 55 or a different material. The etch stop layer 56 may be formed of conventional materials such as silicon nitride (Si₃N₄) for example.

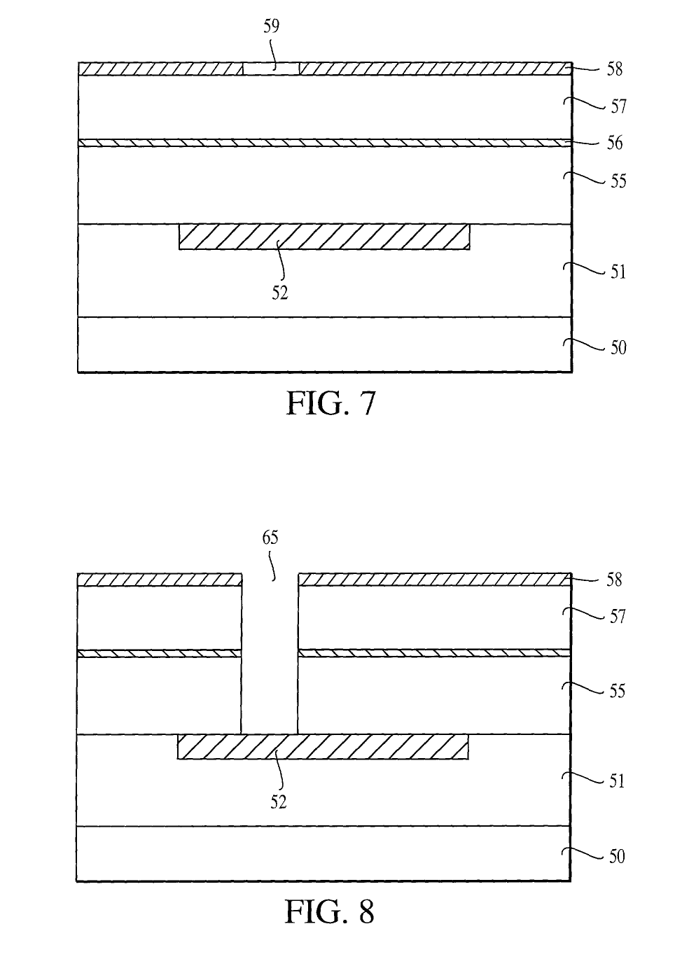

As shown in FIG. 7, a first photoresist layer 58 is formed over the second intermetal insulating layer 57 to a thickness of about 2,000 Angstroms to about 3,000 Angstroms. The first photoresist layer 58 is then patterned with a mask (not shown) having images of a via pattern 59. Thus, as shown in FIG. 8, a via 65 may be formed by first etching through the photoresist layer 58 and into the second intermetal insulating layer 57 with a first etchant, and subsequently etching into the first intermetal insulating layer 55 with a second etchant. The etchants (not shown) may be selected in accordance with the characteristics of the first and second insulating materials 55, 57, so that the insulating materials are selectively etched until the second etchant reaches the metal layer 52.

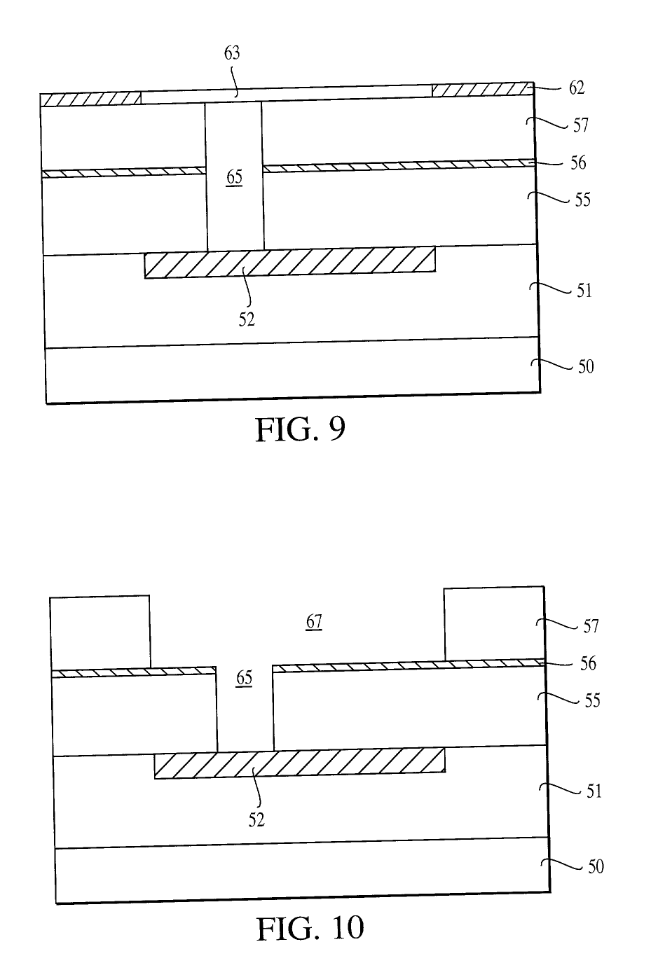

After the formation of the via 65 through the second and first intermetal insulating layers 57, 55, a trench 67 (FIG. 10) may be formed by photolithography. As such, a second photoresist layer 62 (FIG. 9) is formed over the second intermetal insulating layer 57 to a thickness of about 2,000 Angstroms to about 3,000 Angstroms and then patterned with a mask (not shown) having images of a trench pattern 63 (FIG. 9). The trench pattern 63 is then etched into the second intermetal insulating layer 57 using photoresist layer 62 as a mask to form trench 67, as shown in FIG. 10. The thickness of the first intermetal insulating layer 55 defines the depth of the via 65 (FIGS. 8-10). The thickness of the second intermetal insulating layer 57 defines the depth of the trench 67 (FIG. 10).

The etching of the trench 67 may be accomplished using the same etchant employed to form the via 65 (FIG. 8) or a different etchant.

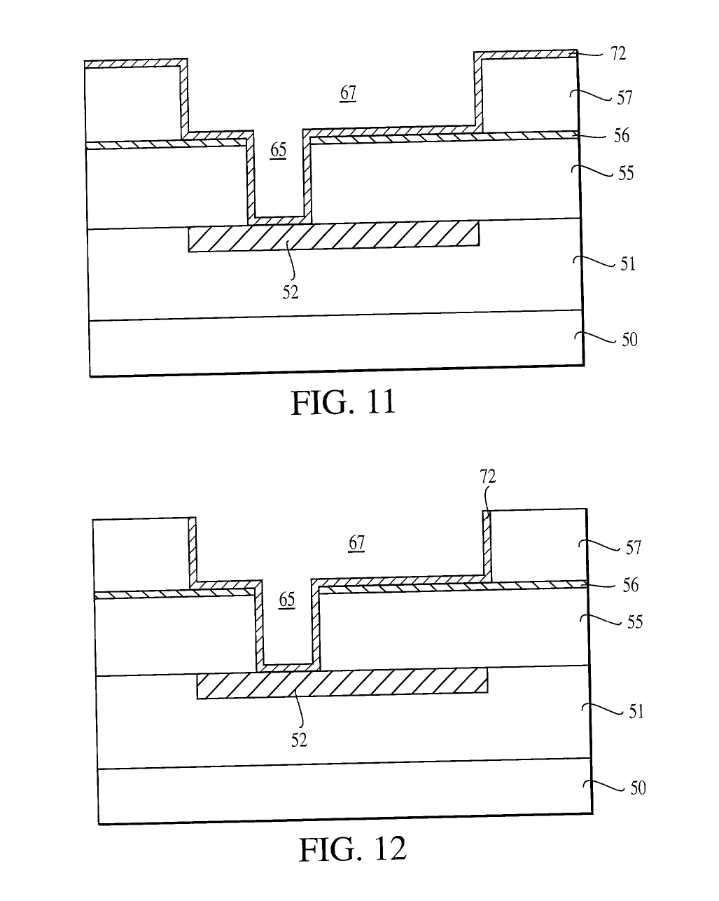

Subsequent to the formation of trench 67, the second photoresist layer 62 is removed so that further steps to create the copper dual damascene structure 100 (FIG. 14) may be carried out. As such, a diffusion barrier layer 72 (FIG. 11) is formed on the via 65 and the trench 67 to a thickness of about 50 Angstroms to about 200 Angstroms, more preferably of about 100 Angstroms.

In a preferred embodiment, the diffusion barrier layer 72 is formed of titanium-silicon-nitride (Ti—Si—N) by a method described by Min et al. in Metal-organic atomic-layer deposition of titanium-silicon-nitride films, Appl. Phys. Lettrs., Vol. 75, No. 11, pp. 1521-23 (1999), the disclosure of which is incorporated by reference herein. Min et al. have demonstrated that Ti—Si—N films deposited by an organo-metallic atomic layer deposition (ALD) method prevent the diffusion of copper at temperatures up to 800° C. for about 60 minutes. According to the organo-metallic ALD technique described by Min et al., Ti—Si—N films are deposited at a low temperature of about 180° C. using a sequential supply of Ti[N(CH₃)₂]₄ [tetrakis (dimethylamido) titanium: TDMAT], SiH₄ (silane) and NH₃ (ammonia). While the reactor pressure is maintained at 133 Pa, TDMAT is delivered from the bubbler maintained at 30° C. to the reactor using argon (Ar) (70 sccm) as a carrier gas. The flow rates of SiH₄ and NH₃ (forming gas with 10% SiH₄/90% Ar) diluted in argon are fixed at 70 sccm. The Ti—N—Si films formed by the above-described ALD technique prevent the diffusion of copper at temperatures up to 800° C. for about 60 minutes, and provide a step coverage of about 100%. As the aspect ratio of via/trench increases, maintaining a good step coverage is particularly important for the Ti—Si—N diffusion barrier layer 72 deposited especially on the sidewalls of the via 65 and trench 67.

Although in a preferred embodiment of the invention the Ti—Si—N diffusion barrier layer 72 is simultaneously deposited in both the via 65 and the trench 67, the invention is not limited to this embodiment. Thus, the Ti—Si—N diffusion barrier layer 72 may be deposited first in the via 65 before the formation of the trench 67, and then in the trench 67 after its respective formation. In any event, after the formation of the diffusion barrier layer 72, horizontal portions of the Ti—Si—N material formed above the surface of the second insulating material 57 are removed by either an etching or a polishing technique to form the structure illustrated in FIG. 12. In a preferred embodiment of the present invention, chemical mechanical polishing (CMP) is used to polish away excess Ti—Si—N material above the second insulating material 57 and the trench level. This way, the second insulating material 57 acts as a polishing stop layer when CMP is used.

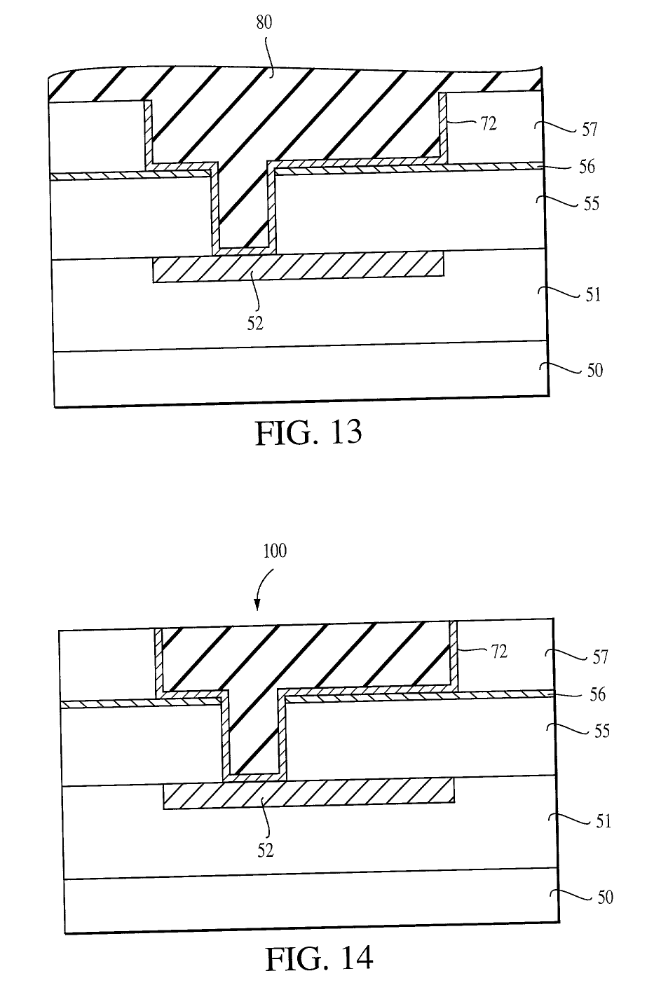

As illustrated in FIG. 13, a conductive material 80 comprising copper (Cu) is next deposited to fill in both the via 65 and the trench 67. In an exemplary embodiment, the copper is selectively deposited by CVD as described by Kaloyeros et al. in Blanket And Selective Copper CVD From Cu (fod)₂ For Multilevel Metallization, Mat. Res. Soc. Symp. Proc., Vol. 181 (1990), the disclosure of which is incorporated by reference herein. Studies of blanket and selective low-temperature metal-organic chemical vapor deposition (LTMOCVD) of copper have been conducted by Kaloyeros et al. at 300-400° C. in an atmosphere of pure H₂ or Ar from the β-diketonate precursor bis(6,6,7,8,8,8-heptafluoro-2,2-dimetyl 1-3,5-octanedino) copper (II), Cu (fod)₂. According to one selective LTMOCVD technique proposed by Kaloyeros et al., the reactor is first pumped down to a base pressure of less than 5×10⁻⁷ torr. Subsequently, the source compound is introduced into the sublimator which is heated to 40-75° C. A mass flow controller is employed to control the flow of the mixed gas/precursor into the reactor. Copper deposition is carried out using argon (Ar) and hydrogen (H₂) as the carrier gases. The substrate 50 is heated to about 300-400° C., while the pressure during deposition ranges from about 1 torr to about 10 torr, at a gas flow range of about 30 sccm to about 55 sccm.

After the deposition of the copper material 80, excess copper formed above the surface of the second insulating material 57 may be removed by either an etching or a polishing technique to form the copper dual damascene structure 100 illustrated in FIG. 14. In a preferred embodiment of the present invention, chemical mechanical polishing (CMP) is used to polish away excess copper above the second insulating material 57 and the trench level. This way, the second insulating material 57 acts as a polishing stop layer when CMP is used.

The selective deposition of copper by CVD that was described above is not the only method that could be employed for forming the conductive material 80. For example, according to another embodiment of the invention, copper can be selectively deposited by an electroless plating technique, which is more attractive than conventional electroplating methods. According to studies done by Shacham-Diamand et al. printed in Copper electroless deposition technology for ultra-large-scale-integration (ULSI) metallization, Microelectronic Engineering, Vol. 33, pp. 47-58 (1997), the disclosure of which is incorporated by reference herein, elecroless plating has a very high selectivity, excellent step coverage and good via/trench filling because of the very thin seed layers formed by this method. Electroless plating is also more advantageous than electroplating because of the low cost of tools and materials.

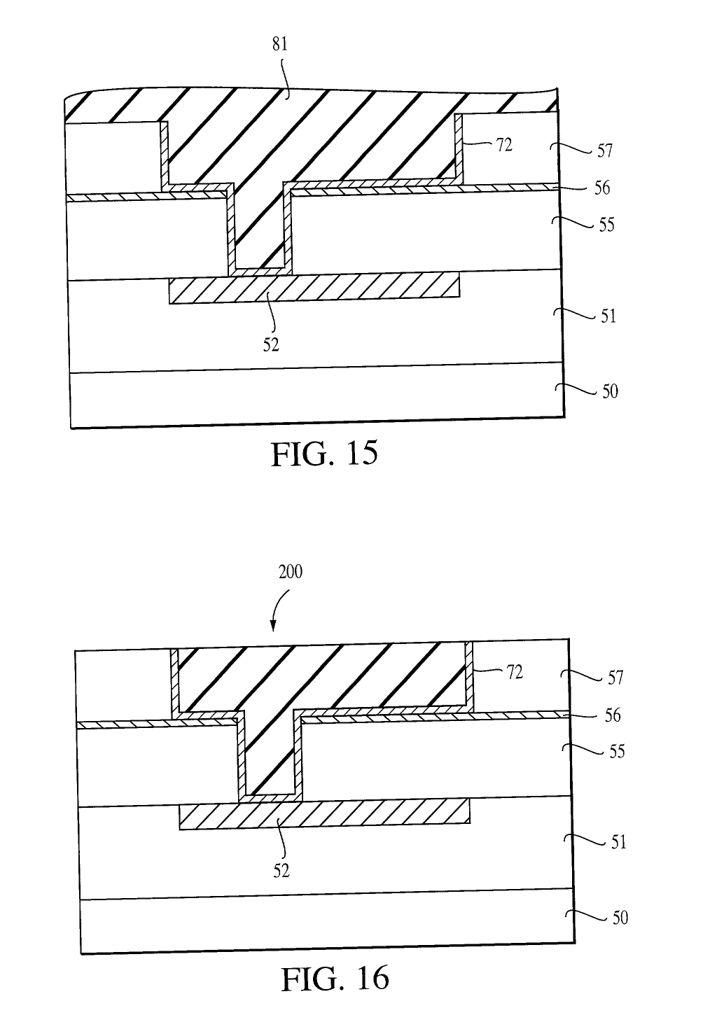

According to Shacham-Diamand et al., three practical seeding methods for the electroless deposition of copper could be used: (1) noble metal seeding, typically on gold, palladium or platinum; (2) copper seeding using an aluminum sacrificial layer; and (3) wet activation of surfaces using a contact displacement method. Shacham-Diamand et al. have successfully used the third method to deposit copper on Ti/TiN or TiN/AlCu at room temperature. Accordingly, in an exemplary embodiment of the present invention, contact displacement copper deposition is used to first selectively activate the Ti—Si—N diffusion barrier layer 72, after which selective electroless copper deposition is employed to obtain a copper layer 81 (FIG. 15). Copper deposition by contact displacement offers the advantage of room temperature, which in turn allows many low dielectric constant organic and/or inorganic materials to be used as the material of choice for interlayer dielectrics, such as the first and second intermetal insulating layers 55, 57.

After the deposition of the copper material 81 (FIG. 15), excess copper formed above the surface of the second insulating material 57 may be removed by either an etching or a polishing technique to form a copper dual damascene structure 200 illustrated in FIG. 16. In a preferred embodiment of the present invention, chemical mechanical polishing (CMP) is used to polish away excess copper above the second insulating material 57 and the trench level. This way, the second insulating material 57 acts as a polishing stop layer when CMP is used.

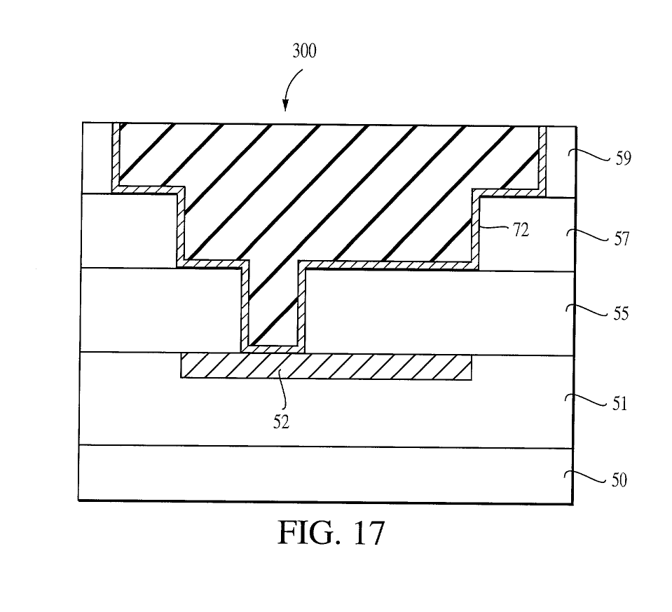

Although only one copper dual damascene structure 100, 200 is shown in FIG. 14 and FIG. 16, respectively, it must be readily apparent to those skilled in the art that in fact any number of such copper dual damascene structures may be formed on the substrate 50. Also, although the exemplary embodiments described above refer to the formation of a copper dual damascene structure 100, 200, the invention is further applicable to other types of damascene structures, for example triple damascene structures, as long as they include a Ti—Si—N diffusion barrier layer and copper selectively deposited by the methods described in detail above. For example, FIG. 17 illustrates a triple damascene structure 300 with three intermetal insulating layers 55, 57, 59 (which could comprise same or different insulating materials) formed over the substrate 50 and in which vias and trenches are filled simultaneously with the selectively deposited copper by the methods described above.

In addition, further steps to create a functional memory cell may be carried out. Thus, additional multilevel interconnect layers and associated dielectric layers could be formed to create operative electrical paths from any of the copper damascene structures 100, 200, 300 to appropriate regions of a circuit intergated on substrate 50.

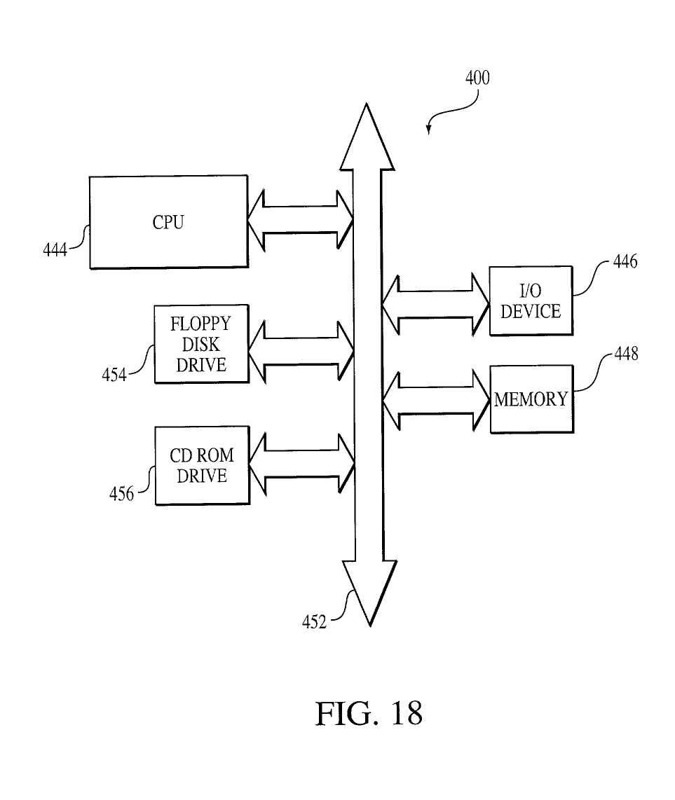

A typical processor-based system 400 which includes a memory circuit 448, for example a DRAM, one or both of which contain damascene structures, such as the copper damascene structures 100, 200, 300, according to the present invention is illustrated in FIG. 18. A processor system, such as a computer system, generally comprises a central processing unit (CPU) 444, such as a microprocessor, a digital signal processor, or other programmable digital logic devices, which communicates with an input/output (I/O) device 446 over a bus 452. The memory 448 communicates with the system over bus 452.

In the case of a computer system, the processor system may include peripheral devices such as a floppy disk drive 454 and a compact disk (CD) ROM drive 456 which also communicate with CPU 444 over the bus 452. Memory 448 is preferably constructed as an integrated circuit, which includes one or more copper damascene structures 100, 200, 300. If desired, the memory 448 may be combined with the processor, for example CPU 444, in a single integrated circuit.

The above description and drawings are only to be considered illustrative of exemplary embodiments which achieve the features and advantages of the present invention. Modification and substitutions to specific process conditions and structures can be made without departing from the spirit and scope of the present invention. Accordingly, the invention is not to be considered as being limited by the foregoing description and drawings, but is only limited by the scope of the appended claims.

What is claimed as new and desired to be protected by Letters Patent of the United States is:

1. A method of forming a copper damascene structure, said method comprising the steps of:
forming a first opening through a first insulating layer;
forming a second opening through a second insulating layer which is provided over said first insulating layer, said first opening being in communication with said second opening;
forming a titanium-siticon-nitride layer in contact with said first and second openings; and
providing a copper layer in said first and second openings.

2. The method of claim 1, wherein said first insulating layer includes oxide material.

3. The method of claim 1, wherein said first insulating layer includes a material selected from the group consisting of polyimide, spin-on-polymers, flare, polyarylethers, parylene, polytetrafluoroethylene, benzocyclobutene, SILK, fluorinated silicon oxide, hydrogen silsesquioxane and NANOGLASS.

4. The method of claim 1, wherein said first insulating layer is formed by deposition to a thickness of about 2,000 to 15,000 Angstroms.

5. The method of claim 4, wherein said first insulating layer is formed by deposition to a thickness of about 6,000 to 10,000 Angstroms.

6. The method of claim 1, wherein said second insulating layer includes oxide material.

7. The method of claim 1, wherein said second insulating layer includes a material selected from the group consisting of polyimide, spin-on-polymers, flare, polyarylethers, parylene, polytetrafluoroethylene, benzocyclobutene, SILK, fluorinated silicon oxide, hydrogen silsesquioxane and NANOGLASS.

8. The method of claim 1, wherein said second insulating layer is formed by deposition to a thickness of about 2,000 to 15,000 Angstroms.

9. The method of claim 8, wherein said second insulating layer is formed by deposition to a thickness of about 6,000 to 10,000 Angstroms.

10. The method of claim 1, wherein said first and second insulating layers are formed of same material.

11. The method of claim 1, wherein said titanium-silicon-nitride layer is formed by metal-organic atomic-layer deposition.

12. The method of claim 11, wherein said titanium-silicon-nitride layer is deposited at a temperature of about 180° C.

13. The method of claim 1, wherein said copper layer is selectively deposited by chemical vapor deposition.

14. The method of claim 13, wherein said copper layer is selectively deposited at a temperature of about 300° C. to about 400° C.

15. The method of claim 14, wherein said copper layer is selectively deposited in an atmosphere of pure hydrogen from the β-diketonate precursor bis(6,6,7,8,8,8-heptafluoro-2,2-dimetyl1-3,5-octanedino) copper (II).

16. The method of claim 14, wherein said copper layer is selectively deposited in an atmosphere of pure argon from the β-diketonate precursor bis(6,6,7,8,8,8-heptafluoro-2,2-dimetyl 1-3,5-octanedino) copper (II).

17. The method of claim 1 further comprising the act of chemical mechanical polishing said titanium-silicon-nitride layer.

18. The method of claim 1 further comprising the act of chemical mechanical polishing said copper layer.

19. A dual damascene structure comprising:
a substrate;
a metal layer provided within said substrate;
a first insulating layer located over said substrate;
a via situated within said first insulating layer and extending to at least a portion of said metal layer, said via being lined with a titanium-silicon-nitride layer and filled with a copper material;
a second insulating layer located over said first insulating layer;
a trench situated within said second insulating layer and extending to said via, said trench being lined with said titanium-silicon-nitride layer and filled with said copper material.

20. The dual damascene structure of claim 19, wherein said first insulating layer includes a material selected from the group consisting of polyimide, spin-on-polymers, flare, polyarylethers, parylene, polytetrafluoroethylene, benzocyclobutene, SILK, fluorinated silicon oxide, hydrogen silsesquioxane and NANOGLASS.

21. The dual damascene structure of claim 19, wherein said first insulating layer includes silicon dioxide.

22. The dual damascene structure of claim 19, wherein said first insulating layer has a thickness of about 2,000 to 15,000 Angstroms.

23. The dual damascene structure of claim 19, wherein said second insulating layer includes a material selected from the group consisting of polyimide, spin-on-polymers, flare, polyarylethers, parylene, polytetrafluoroethylene, benzocyclobutene, SILK, fluorinated silicon oxide, hydrogen silsesquioxane and NANOGLASS.

24. The dual damascene structure of claim 19, wherein said second insulating layer includes silicon dioxide.

25. The dual damascene structure of claim 19, wherein said second insulating layer has a thickness of about 2,000 to 15,000 Angstroms.

26. The dual damascene structure of claim 19, wherein said titanium-silicon-nitride layer has a thickness of about 50 Angstroms to about 200 Angstroms.

27. The dual damascene structure of claim 26, wherein said titanium-silicon-nitride layer has a thickness of about 100 Angstroms.

28. The dual damascene structure of claim 19, wherein said copper material includes copper or a copper alloy.

29. The dual damascene structure of claim 19, wherein said substrate is a semiconductor substrate.

30. The dual damascene structure of claim 29, wherein said substrate is a silicon substrate.

31. A damascene structure comprising:
a substrate;
a metal layer provided within said substrate;
at least one insulating layer located over said substrate; and
at least one opening situated within said at least one insulating layer and extending to at least a portion of said metal layer, said opening being lined with a titanium-silicon-nitride layer and filled with a copper material;

32. The damascene structure of claim 31, wherein said at least one insulating layer includes a material selected from the group consisting of polyimide, spin-on-polymers, flare, polyarylethers, parylene, polytetrafluoroethylene, benzocyclobutene, SILK, fluorinated silicon oxide, hydrogen silsesquioxane and NANOGLASS.

33. The damascene structure of claim 31, wherein said at lest one insulating layer includes silicon dioxide.

34. The damascene structure of claim 31, wherein said at least one insulating layer has a thickness of about 2,000 to 15,000 Angstroms.

35. The damascene structure of claim 31, wherein said titanium-silicon-nitride layer has a thickness of about 50 Angstroms to about 200 Angstroms.

36. The damascene structure of claim 35, wherein said titanium-silicon-nitride layer has a thickness of about 100 Angstroms.

37. The damascene structure of clam 31, wherein said copper material includes copper or a copper alloy.

38. The damascene structure of clam 31, wherein said substrate is a semiconductor substrate.

39. The damascene structure of claim 38, wherein said substrate is a silicon substrate.

40. A processor-based system comprising:
a processor; and
an integrated circuit coupled to said processor, at least one of said processor and integrated circuit including a damascene structure, said damascene structure comprising a metal layer over a substrate, at least one insulating layer located over said metal layer, and at least one opening situated within said at least one insulating layer and extending to at least a portion of said metal layer, said opening being lined with a titanium-silicon-nitride layer and filled with copper.

41. The processor-based system of claim 40, wherein said processor and said integrated circuit are integrated on same chip.
